(19) United States
(12) Patent Application Publication
(10) Pub. No.: US 2013/0049778 A1
(43) Pub. Date: Feb. 28, 2013

(54) BALANCING RESISTOR TESTING APPARATUS

(71) Applicants: FU-SEN YANG, Shenzhen City (CN); YUN BAI, Shenzhen City (CN); SONG-LIN TONG, Shenzhen City (CN)

(72) Inventors: FU-SEN YANG, Shenzhen City (CN); YUN BAI, Shenzhen City (CN); SONG-LIN TONG, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/537,062

(22) Filed: Jun. 29, 2012

(30) Foreign Application Priority Data
Aug. 31, 2011 (CN) 201110254648.8

(51) Int. Cl. G01R 27/00

(52) U.S. Cl. 324/714

(57) ABSTRACT

A balancing resistor testing apparatus is configured for acquiring a resistance of a balancing resistor electronically connected to a supercapacitor of a series supercapacitor assembly in parallel. The balancing resistor testing apparatus includes a controller and a digital potentiometer. The controller detects a voltage across each supercapacitor of the series supercapacitor. The digital potentiometer comprising a plurality of variable resistors each of which is electronically connected to a supercapacitor in parallel, the controller controls the digital potentiometer to continuously adjust the effective resistance of each potentiometer until the controller detects that each supercapacitor has the same or very similar voltage.

### BACKGROUND

1. Technical Field

The exemplary disclosure generally relates to balancing resistor testing apparatuses, particularly to a balancing resistor testing apparatus for testing a resistance of a balancing resistor electronically connected to a series supercapacitor assembly.

2. Description of Related Art

A series supercapacitor assembly is generally composed of two or more supercapacitors connected in series. Since each of the supercapacitors have different internal resistances, voltage of each supercapacitor is different from each other, which will affect a capability of the series supercapacitor assembly.

One way to decrease the differences in the voltages between the supercapacitors is by connecting a balancing resistor to each supercapacitor in parallel. The balancing resistor acts like a big voltage divider and counteracts the effects of variance in internal resistances of the supercapacitors to help the supercapacitors to approximately have a same voltage. One way to choose an appropriate resistance of each balancing resistor is by connecting a resistor to each supercapacitor on a printed circuit board (PCB), and detecting the voltage of each supercapacitor. If there is a difference between the respective voltages of the supercapacitors, then removing the resistor from the PCB and connecting another resistor having a different resistance on the PCB until the supercapacitors share an equal voltage. However, the aforementioned method requires replacing the resistors many times which will increase a testing time and may destroy the supercapacitors.

Therefore, there is room for improvement within the art.

### BRIEF DESCRIPTION OF THE DRAWINGS

Many aspects of the embodiments can be better understood with reference to the drawings. In the drawings, the emphasis is placed upon clearly illustrating the principles of the disclosure.

FIG. 1 shows a block diagram of an exemplary embodiment of a balancing resistor testing apparatus having a controller, a charging circuit, a discharging circuit, a digital potentiometer and a display.

FIG. 2 is a schematic circuit diagram of a number of supercapacitors connected in series (series supercapacitor assembly), and the controller, the charging circuit and the discharging circuit of the balancing resistor testing apparatus shown in FIG. 1.

FIG. 3 is a schematic circuit diagram of the series supercapacitor assembly shown in FIG. 2 and the digital potentiometer of the balancing resistor testing apparatus shown in FIG. 1.

FIG. 4 is a schematic equivalent circuit diagram of series supercapacitor assembly shown in FIG. 2 and the digital potentiometer shown in FIG. 3.

### DETAILED DESCRIPTION

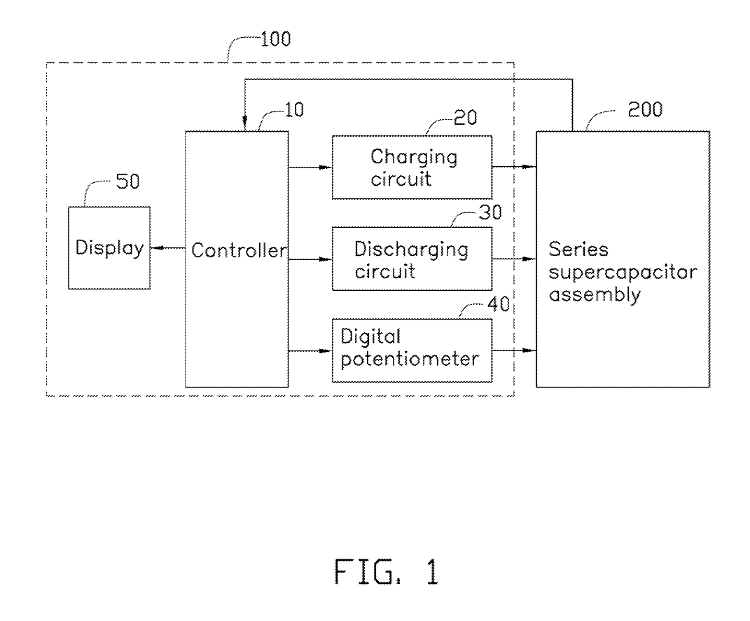

Referring to FIG. 1, an exemplary embodiment of a balancing resistor testing apparatus 100 for testing a resistance of balancing resistor electronically connected to a supercapacitor of a series supercapacitor assembly 200 in parallel is presented. The testing apparatus 100 includes a controller 10, a charging circuit 20, a discharging circuit 30, a digital potentiometer 40 and a display 50. The controller 10 controls the charging circuit 20 and the discharging circuit 30 to charge and discharge the individual supercapacitors in the series supercapacitor assembly 200, thereby testing a voltage of each supercapacitor of the series supercapacitor 200. The digital potentiometer 40 includes a plurality of variable resistors which are respectively and electrically connected to the corresponding supercapacitor in parallel. The digital potentiometer 40 adjusts resistance of each variable resistor under the control of the controller 10 to make voltages of all of the supercapacitors are approximately the same.

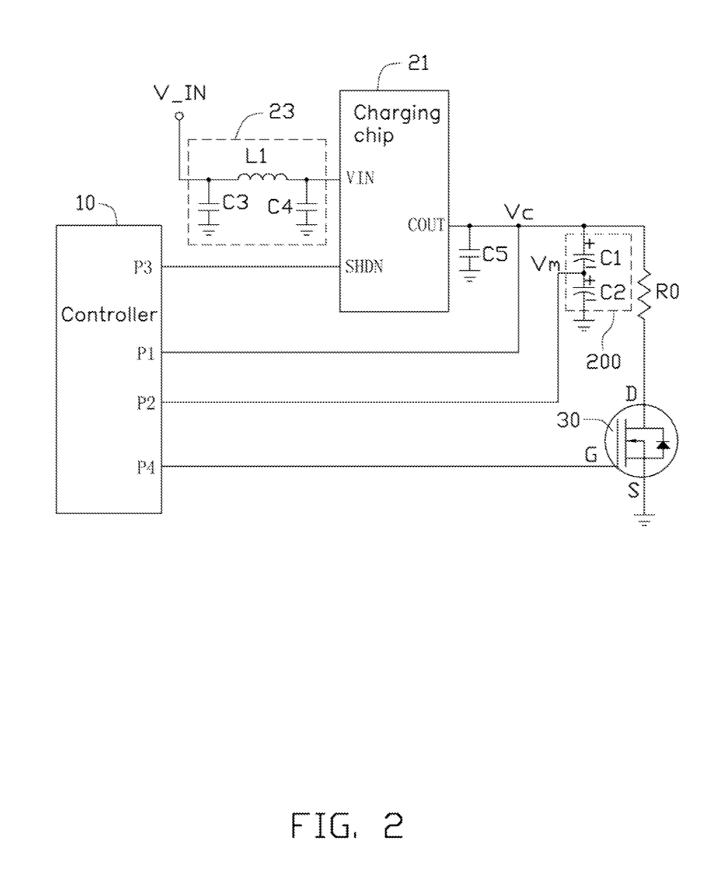

Referring to FIG. 2, the series supercapacitor 200 includes at least two supercapacitors, for example, a first supercapacitor C1 and a second supercapacitor C2, electrically connected in series.

The controller 10 includes a first voltage detecting pin P1, a second voltage detecting pin P2, a first controlling pin P3 and a second controlling pin P4. The controller 10 detects the voltages across the first supercapacitor C1 and the second supercapacitor C2 via the first voltage detecting pin P1 and the second voltage detecting pin P2 respectively. The controller 10 controls the charging circuit 20 to charge the series supercapacitor 200 via the first controlling pin P3, and controls the discharging circuit 30 to discharge the series supercapacitor 200 via the second controlling pin P4.

The charging circuit 20 includes a charging chip 21 and a first filter circuit 23 and a second filter circuit. The charging chip 21 includes a power input pin VIN, a charging current output pin COUT and an enable pin SHDN. The power input pin VIN is electrically connected to a power supply V-IN. In one embodiment, the power supply V-IN can be a 5 volt power supply, and the power input pin VIN is electrically connected to the 5 volt power supply via the first filter circuit 23. The charging current output pin COUT is electrically connected to the series supercapacitor assembly 200 and ground in series, that is, the first supercapacitor C1 and the second supercapacitor C2 are connected between the charging current output pin COUT and ground in series. The enable pin SHDN is electronically connected to the first controlling pin P3. When the controller 10 outputs a first voltage signal, e.g. a low level voltage signal (e.g. logic 0) to the enable pin SHDN via the first controlling pin P3 to activate the charging chip 21, the charging chip 21 converts a current outputted from the power supply V-IN to a charging current, which is then forward to the series supercapacitor assembly 200 to charge the series supercapacitor assembly 200. When the controller 10 outputs a second voltage signal, e.g. a high level voltage signal (e.g. logic 1) to the enable pin SHDN via the first controlling pin P3 to deactivate the charging chip 21, the charging chip 21 stops charging the series supercapacitor assembly 200. In one embodiment, the charging chip 21 can be a programmable supercapacitor charger LTC3225 made by Linear Technology Corporation, and the charging chip 21 is activated when the enable pin SHDN is at a low level voltage (e.g. logic 0).

The first filter circuit 23 reduces noise induced at the power input pin VIN. The filter circuit 23 includes an inductor L1, a first filter capacitor C3, and a second filter capacitor C4. The inductor L1 is electronically connected between the power supply V-IN and the power input pin VIN in series, a node between the inductor L1 and the power supply V-IN is grounded via the first filter capacitor C3, and a node between the inductor L1 and the power input pin VIN is grounded via the second filter capacitor C4. The second filter circuit is substantially third filter capacitor C5, in one example. The third capacitor C5 is electronically connected between the charging current output pin COUT and the ground in series to reduce noise induced at the charging current output pin COUT.

The discharging circuit 30 is an electronic switch connected between the ground and a node between the charging current output pin COUT and the series supercapacitor assembly 200. The electronic switch is further electronically connected to the controller 10. When the charging circuit 20 charges the series supercapacitor assembly 200, the controller 10 controls the electronic switch to turn off. When the charging circuit 20 stops charging the series supercapacitor assembly 200, the controller 10 controls the electronic switch to turn on, thereby the series supercapacitor assembly 200 can discharge to ground via the electronic switch.

In the exemplary embodiment, the electronic switch is a N channel Metal-Oxide-Semiconductor Field-Effect Transistor (MOSFET). A drain D of the N channel MOSFET is electronically connected to a node between the charging current output pin COUT and the series supercapacitor assembly 200 via a discharging resistor R0, a gate G of the N channel MOSFET is electronically connected to the second controlling pin P4, and a source S of the N channel MOSFET is grounded. When the controller 10 outputs a low level voltage signal (logic 0) to the gate G via the second controlling pin P4, the N channel MOSFET is turned off. When the controller 10 outputs a high level voltage signal (logic 1) to the gate G via the second controlling pin P4, the N channel MOSFET is turned on. The electronic switch can be a NPN type bipolar junction transistor (BJT), of which the base, the emitter and the collector have electronic connections to peripheral circuits respectively corresponding to the gate G, the source S and the drain D of the N channel MOSFET.

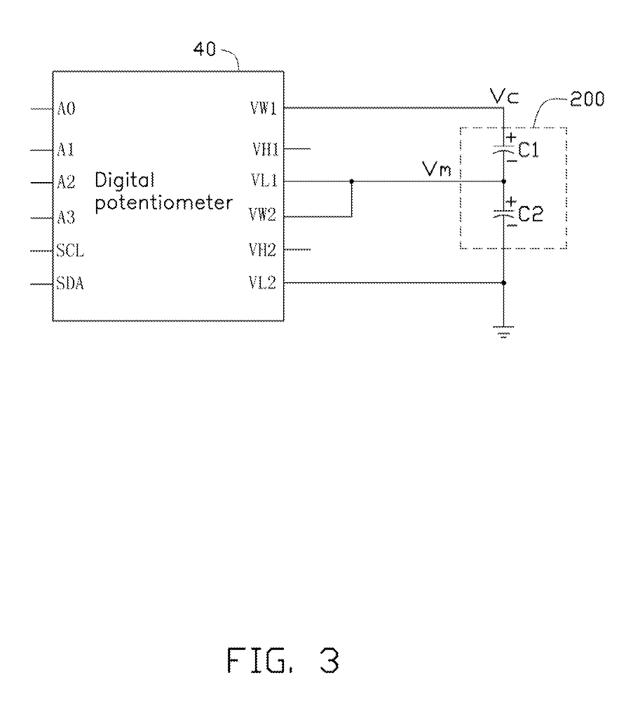

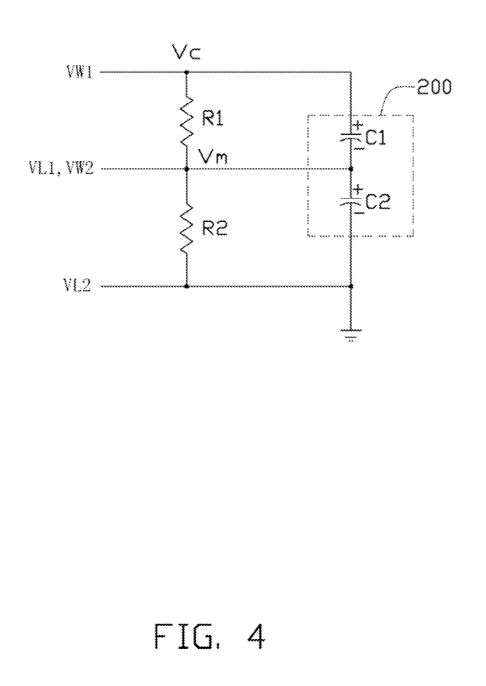

Referring to FIG. 3 and FIG. 4, the digital potentiometer 40 includes a clock pin SCL, a data pin SDA, a first wiper pin VW1, a first connecting pin VH1, a second connecting pin VL1, a second wiper pin VW2, a third connecting pin VH2, a fourth connecting pin VL2, and four address pins A0-A3. The first wiper pin VW1, the first connecting pin VH1 and the second connecting pin VL1 are electronically connected to a first variable resistor of the digital potentiometer 40. The second wiper pin VW2, the third connecting pin VH2 and the fourth connecting pin VL2 are electronically connected to a second variable resistor of the digital potentiometer 40. The first and the second wiper pins VW1, VW2 each have a wiper output. The first and second connecting pins VH1, VL1 are electrically connected to the end terminals of the first variable resistor. The third and fourth connecting pins VH2, VL2 are electrically connected to the end terminals of the second variable resistor. The clock pin SCL and the data pin SDA communicate serially with the controller 10. The controller 10 chooses the first and second potentiometers via the address pins A0-A3. For example, the controller 10 may output logic levels 0,0,0, and 0 to the address pins A0-A3 when the controller 10 chooses to control the first potentiometer, and output logic levels 0,0,0,and 1 to the address pins A0-A3 when the controller 10 chooses to control the second potentiometer. Since the clock pin SCL, the data pin SDA and the address pins A0-A3 are connected to the controller 10 in a well-known way, the connection circuit between the controller 10 and the clock pin SCL, the data pin SDA and the address pins A0-A3 are not shown in the FIGS. 1-4. In the exemplary embodiment, the type of the digital potentiometer 40 is X9241 made by XICOR, and includes four variable resistors.

The first wiper pin VW1 and the second connecting pin VL1 are respectively connected to a positive terminal and negative terminal of the first supercapacitor C1, the first connecting pin VH1 is not connected. An effective resistance of the first variable resistor connected to the first supercapacitor C1 in parallel is labeled as a first effective resistor R1, the effective resistance of the second variable resistor connected to the second supercapacitor C2 in parallel is labeled as a second effective resistor R2. The digital potentiometer 40 adjusts the resistance of the first and second effective resistors R1, R2 according to the control of the controller 10. In the exemplary embodiment, the first and second effective resistors R1, R2 have the same resistance.

When the resistances of the first and second effective resistors R1, R2 change, the voltages across the first and second supercapacitors C1, C2 correspondingly change. The resistances of the first and second effective resistors R1, R2, are changed until the voltages across the first and second supercapacitors C1, C2 are the same, or any difference between the voltages across the first and second supercapacitors C1, C2 is within a predetermined difference range. At this time, the resistance of the first effective resistor R1 is equivalent to the resistance of a balancing resistor of the first supercapacitor C1, and the resistance of the second effective resistor R2 is equivalent to the resistance of a balancing resistor of the second supercapacitor C2.

The display 50 displays the resistance values of the first and second effective resistors R1, R2. In the exemplary embodiment, since the first and second effective resistors R1 and R1 have the same resistance, the display 50 only shows one resistance. When the controller 10 detects that the voltages across the first and second supercapacitors C1, C2 are the same, or any difference between the voltages across the first and second supercapacitors C1, C2 is within a predetermined difference range, the controller 10 records the resistances of the first and the second effective resistors R1, R2, which is then forwarded to the display 50. Thus, a tester can easily know the resistances of the balancing resistors of the first and second supercapacitors C1, C2 from the display 50.

The working process of the balancing resistor testing apparatus 100 can be carried out by, but is not limited to, the following steps. The first and second voltage detecting pins P1 and P2 of the controller 10 are connected to the positive terminals of the first and second supercapacitors C1, C2. The controller 10 sets the resistances of the first and second effective resistors R1, R2 via the digital potentiometer 40, at this time, the first and second effective resistors R1, R2 preferably have a small resistance. The controller 10 then controls the charging circuit 20 to charge the series supercapacitor 200. After charging, the voltage of the positive terminal of the first supercapacitor C1 is labeled as Vc, the voltage of the positive terminal of the second supercapacitor C2 is labeled as Vm, and the ratio of the voltage Vc and the voltage Vm (Vc/Vm) is labeled as A. Controller 10 detects the voltages Vc and Vm via the first and second voltage detecting pins P1 and P2, and computes and records the ratio A. After that, the controller 10 controls the discharging circuit 30 to discharge the series supercapacitor 200. After discharging, the controller 10 controls the charging circuit 20 to charge the series supercapacitor 200 again, and detects the voltages Vc and Vm and computes the ratio A. The balancing resistor testing apparatus 100 repeats the above process N (e.g. N=10) times, the controller 10 can then compute the average value of N number of ratio A, if the average value equals 2 or the difference between the average value and 2 is within a determined difference range, the voltage across the first supercapacitor C1 can be considered equal to the voltage across the second supercapacitor C2, at this time, the resistance of the first effective resistor R1 is equivalent to the resistance of the balancing resistor of the first supercapacitor C1, and the resistance of the second effective resistor R2 is equivalent to the resistance of the balancing resistor of the second supercapacitor C2. The controller 10 then controls the display 50 to display the resistances of the first and second effective resistors R1, R2.

If the difference between the average value and 2 is outside the determined difference range, the controller 10 controls the digital potentiometer 40 to increase by equal increments the resistances of the first and second effective resistors R1, R2,. The balancing resistor testing apparatus 100 then repeats the aforesaid process to detect the voltages cross the first and second supercapacitors C1, C2, until the voltages across the first and second supercapacitors C1, C2 are the same.

The controller 10 controls the digital potentiometer 40 to adjust each potentiometer connected to a supercapacitor, until voltages across the supercapacitors are the same, at this time, the effective value of the variable resistor is equivalent to the resistance of a balancing resistor required for the supercapacitor. Hence, a tester can easily know the resistance of the balancing resistors of each supercapacitor of the series supercapacitor assembly 200, and does not need to keep changing the resistors connected to the supercapacitors in parallel on a PCB, which will save testing time.

It is believed that the exemplary embodiments and their advantages will be understood from the foregoing description, and it will be apparent that various changes may be made thereto without departing from the spirit and scope of the disclosure or sacrificing all of its material advantages, the examples hereinbefore described merely being preferred or exemplary embodiments of the disclosure.

What is claimed is:

1. A balancing resistor testing apparatus configured for acquiring a resistance of balancing resistor electronically connected to a supercapacitor of a series supercapacitor assembly in parallel, comprising:
a controller electronically connected to each supercapacitor of the series supercapacitor assembly configured for detecting a voltage across each supercapacitor;
a digital potentiometer electronically connected to the controller, the digital potentiometer comprising a plurality of variable resistors, each of the variable resistors respectively and electronically connected to a corresponding supercapacitor in parallel; the controller controlling the digital potentiometer to continuously adjust effective resistance of each of the variable resistors until the controller detects that differences between the voltages of the supercapacitors are within a predetermined difference range.

2. The balancing resistor testing apparatus as claimed in claim 1, wherein the differences between the voltages of the supercapacitors are within a predetermined difference range when the effective resistance of each potentiometer is equivalent to the resistance of the balancing resistor of the corresponding supercapacitor.

3. The balancing resistor testing apparatus as claimed in claim 1, further comprising a display electronically connected to the controller, wherein the controller controls the display to display the effective resistance of each variable resistor when the controller detects the differences between the voltages of the supercapacitors are within the predetermined difference range.

4. The balancing resistor testing apparatus as claimed in claim 1, further comprising a charging circuit electronically connected to the controller, wherein the charging circuit charges the series supercapacitor assembly before the controller detects the voltage across the supercapacitors.

5. The balancing resistor testing apparatus as claimed in claim 4, further comprising a power supply, wherein the charging circuit comprises a charging chip comprising a power input pin electrically connected to the power supply, a charging current output pin grounded via the series supercapacitor assembly, and an enable pin electronically connected to the controller.

6. The balancing resistor testing apparatus as claimed in claim 5, wherein the charging chip converts a current outputted from the power supply to a charging current and sends the charging current to the series supercapacitor assembly via the charging current output pin, wherein the controller activates or deactivates the charging chip by controlling voltages of the enable pin.

7. The balancing resistor testing apparatus as claimed in claim 5, wherein the charging circuit further comprising a first filter circuit for reducing noise induced at the power input pin, the first filter circuit comprising an inductor, a first filter capacitor and a second filter capacitor, the inductor is electronically connected between the power supply and the power input pin, a node between the inductor and the power supply is grounded via the first filter capacitor, a node between the inductor and the power input pin is grounded via the second filter capacitor.

8. The balancing resistor testing apparatus as claimed in claim 4, further comprising a discharging circuit electronically connected to the controller and the series supercapacitor assembly, wherein the discharging circuit discharges the series supercapacitor after the controller detects the voltages across the supercapacitors.

9. The balancing resistor testing apparatus as claimed in claim 8, wherein the discharging circuit is an electronic switch electronically connected between ground and a node between the charging circuit and the series supercapacitor assembly, the electronic switch further electronically connected to the controller.

10. The balancing resistor testing apparatus as claimed in claim 9, wherein the controller controls the electronic switch to turn off when the charging circuit charges the series supercapacitor, and the controller controls the electronic switch to turn on when the charging circuit stops charging the series supercapacitor.

11. The balancing resistor testing apparatus as claimed in claim 9, further comprising a discharging resistor, wherein the electronic switch is a N channel Metal-Oxide-Semiconductor Field-Effect Transistor (MOSFET), a drain of the N channel MOSFET is electronically connected to a node between the charging circuit and the series supercapacitor assembly via the discharging resistor, a gate of the N channel MOSFET is electronically connected to the controller, and a source of the N channel MOSFET is grounded, the controller turns on or off the N channel MOSFET by controlling the voltage of the gate.

12. The balancing resistor testing apparatus as claimed in claim 9, further comprising a discharging resistor, wherein the electronic switch is a NPN type bipolar junction transistor (BJT), a collector of the NPN type BJT is electronically connected to a node between the charging circuit and the series supercapacitor via the discharging resistor, a base of the NPN type BJT is electronically connected to the controller, a emitter of the NPN type BJT is grounded, the controller turns on or off the NPN type BJT by controlling the voltage of the gate.

13. The balancing resistor testing apparatus as claimed in claim 1, wherein the digital potentiometer comprises a plurality of wiper pins and a plurality of connecting pins, each variable resistor of the digital potentiometer connects a wiper pin and two connecting pins, each variable resistor connects to a positive terminal of the corresponding supercapacitor via the wiper pin connected, and connects to a negative terminal of the corresponding supercapacitor via one of the two connecting pins connected thereto, the other pin of the two connecting pins connected to each variable resistor is not connected.

14. The balancing resistor testing apparatus as claimed in claim 1, wherein the effective resistance of each potentiometer has the same value.
